(19) United States
(12) Patent Application Publication
(10) Pub. No.: US 2026/0359506 A1
(43) Pub. Date: Nov. 12, 2026

(54) COMPUTING DEVICE FOR INDOOR AND OUTDOOR WIDE-AREA SPATIAL MAPPING AND METHOD OF OPERATION THEREOF

(71) Applicant: NAVER CORPORATION, Seongnam-si (KR)

(72) Inventors: Soohyun RYU, Seongnam-si (KR); Suyong YEON, Seongnam-si (KR); Donghwan LEE, Seongnam-si (KR); Youngchan KIM, Seongnam-si (KR); Joohyun PARK, Seongnam-si (KR)

(21) Appl. No.: 19/724,345

(22) Filed: Jun. 29, 2026

Related U.S. Application Data
(63) Continuation of application No. PCT/KR2024/013704, filed on Sep. 10, 2024.

(30) Foreign Application Priority Data
Dec. 29, 2023 (KR) 10-2023-0197241

(51) Int. Cl. G06F 30/13

(52) U.S. Cl. CPC G06F 30/13

(57) ABSTRACT

A computing device for indoor and outdoor wide-area spatial mapping may be configured to acquire a plurality of datasets each having connection point information on at least one connection point for a wide-area space, and register the datasets by mapping the connection points of the datasets based on the connection point information.

### CROSS-REFERENCE TO RELATED APPLICATIONS

This application is a continuation of International Application No. PCT/KR 2024/013704, filed Sep. 10, 2024, which claims the benefit of priority under 35 U.S.C. § 119 to Korean Patent Application No. 10-2023-0197241 filed on Dec. 29, 2023 in the Korean Ministry of Intellectual Property (MOIP), the entire contents of which are incorporated herein by reference.

### BACKGROUND OF THE INVENTION

### Field of the Invention

The present disclosure relates to a computing device for indoor and outdoor wide-area spatial mapping and a method of operation thereof.

### Description of Related Art

Generally, there is a technology in which a device moves around an unknown environment and collects data about the corresponding environment, thereby providing a service using such data. For an indoor and outdoor wide-area space, a plurality of datasets are acquired multiple times for the corresponding wide-area space, and a service for the corresponding wide-area space is provided by registration of such datasets. Here, the registration of the datasets is achieved by matching descriptor information of camera images or LiDAR point clouds. However, as places of environmentally similar but different locations are determined to be the same place, an error may occur in the registration of the datasets. Such an error has a high possibility of occurring for an indoor space of a building having a plurality of environmentally similar floors. Meanwhile, if the datasets are acquired together with a GPS signal, it is possible to provide the service for the corresponding wide-area space without the registration of the datasets. However, for example, reception of the GPS signal may not be possible indoors or in a shaded area due to a building, a tree, or the like.

### BRIEF SUMMARY OF THE INVENTION

The present disclosure describes a computing device for registration between datasets or within a dataset for providing a service for an indoor and outdoor wide-area space, and a method of operation thereof.

The present disclosure describes a computing device that additionally collects information on a registration point and performs registration between datasets or within a dataset using the corresponding information, and a method of operation thereof.

A method of operation of a computing device of the present invention may include acquiring a plurality of datasets each having information on at least one connection point for a wide-area space, and registering the datasets by mapping the connection points of the datasets based on the information.

A computing device of the present invention includes a memory, and a processor connected to the memory and configured to execute at least one instruction stored in the memory, and the processor may be configured to acquire a plurality of datasets each having information on at least one connection point for a wide-area space, and to register the datasets by mapping the connection points of the datasets based on the information.

According to the present disclosure, as each of the datasets includes connection point information, the computing device can more accurately register the datasets using the connection points of the datasets. Specifically, the computing device can register datasets each having connection point information for a connection point of the same location. Thereby, for example, the computing device can more accurately register different datasets, or different sub-datasets within one dataset, respectively collected in different periods, that is, periods separated by an arbitrary time interval. Therefore, a possibility of occurrence of an error in registering the datasets by the computing device can be reduced. In addition, the necessity for the computing device to acquire GPS information together with the datasets can also be eliminated.

### BRIEF DESCRIPTION OF THE DRAWINGS

FIG. 1 is a block diagram illustrating a computing device for indoor and outdoor wide-area spatial mapping according to an embodiment of the present invention;

FIG. 2A is an exemplary diagram for explaining collection paths for each of datasets acquired in the computing device of FIG. 1;

FIG. 2B is an exemplary diagram for explaining registration of datasets by the computing device of FIG. 1;

FIG. 3 is an exemplary diagram for explaining a collection of datasets acquired in the computing device of FIG. 1;

FIG. 4 is a flowchart illustrating a method of operation of a computing device for indoor and outdoor wide-area spatial mapping according to an embodiment of the present invention;

FIG. 5A is an exemplary diagram showing datasets acquired in the computing device of FIG. 1;

FIG. 5B is an exemplary diagram showing datasets updated with connection point information from the datasets of FIG. 5A;

FIG. 5C is an exemplary diagram showing registration of the datasets of FIG. 5B;

FIG. 6 is a flowchart illustrating the steps of acquiring a plurality of datasets each having connection point information for the wide-area space of FIG. 4 according to an embodiment of the present invention;

FIGS. 7A to 7D are exemplary diagrams for explaining a user interface related to FIG. 6;

FIG. 8 is a flowchart illustrating the steps of acquiring a plurality of datasets each having connection point information for the wide-area space of FIG. 4 according to another embodiment of the present invention;

FIG. 9 is a block diagram illustrating an external device for assisting the computing device of FIG. 1 according to one embodiment;

FIG. 10 is a flowchart illustrating a method of operation of an external device for assisting the computing device of FIG. 1 according to an embodiment of the present invention; and

FIGS. 11A to 11E are exemplary diagrams for explaining a user interface related to FIG. 10.

### DETAILED DESCRIPTION OF THE INVENTION

Hereinafter, specific details for carrying out the present disclosure will be described in detail with reference to the accompanying drawings. However, in the following description, if there is a concern of unnecessarily obscuring the gist of the present disclosure, detailed descriptions of widely known functions or configurations will be omitted.

In the accompanying drawings, identical or corresponding components are given identical reference numerals. In addition, in the description of the following embodiments, overlapping descriptions of identical or corresponding components may be omitted. However, even if the description of a component is omitted, it is not intended that such a component be excluded in the disclosed embodiments.

Advantages and features of the disclosed embodiments, and methods for achieving them, will become apparent with reference to the embodiments described below in conjunction with the accompanying drawings. However, the present disclosure is not limited to the embodiments disclosed below, but may be implemented in various different forms, and these embodiments are merely provided to make the present disclosure complete and to fully inform those skilled in the art of the scope of the invention.

Terms used in the present disclosure will be briefly described, and the disclosed embodiments will be described in detail. The terms used in the present disclosure have been selected from general terms that are currently widely used as much as possible while considering the functions in the present disclosure, but these may vary depending on the intention of a person skilled in the related art, precedents, the emergence of new technologies, and the like. In addition, in certain cases, there are terms arbitrarily selected by the applicant, and in this case, the meaning thereof will be described in detail in the corresponding description of the invention. Therefore, the terms used in the present disclosure should be defined based on the meaning of the term and the overall contents of the present disclosure, rather than simply the name of the term.

Singular expressions in the present disclosure include plural expressions unless the context clearly specifies them as singular. In addition, plural expressions include singular expressions unless the context clearly specifies them as plural. Throughout the specification, when a part is said to include a certain component, this means that it may further include other components, rather than excluding other components, unless specifically stated to the contrary.

In addition, the term ‘module’ or ‘unit’ used in the present disclosure means a software or hardware component, and the ‘module’ or ‘unit’ performs certain roles. However, the ‘module’ or ‘unit’ is not meant to be limited to software or hardware. The ‘module’ or ‘unit’ may be configured to reside on an addressable storage medium or may be configured to reproduce one or more processors. Therefore, as an example, the ‘module’ or ‘unit’ may include at least one of components such as software components, object-oriented software components, class components, and task components, and processes, functions, attributes, procedures, subroutines, segments of program code, drivers, firmware, microcode, circuitry, data, databases, data structures, tables, arrays, or variables. The functions provided within the components and ‘modules’ or ‘units’ may be combined into a smaller number of components and ‘modules’ or ‘units’, or may be further separated into additional components and ‘modules’ or ‘units’.

According to the present disclosure, a ‘module’ or ‘unit’ may be implemented by a processor and a memory. ‘Processor’ should be interpreted broadly to include a general-purpose processor, a central processing unit (CPU), a microprocessor, a digital signal processor (DSP), a controller, a microcontroller, a state machine, and the like. In some environments, ‘processor’ may refer to an application-specific integrated circuit (ASIC), a programmable logic device (PLD), a field programmable gate array (FPGA), and the like. ‘Processor’ may refer to a combination of processing devices, such as, for example, a combination of a DSP and a microprocessor, a combination of a plurality of microprocessors, a combination of one or more microprocessors in conjunction with a DSP core, or any other combination of such configurations. In addition, ‘memory’ should be interpreted broadly to include any electronic component capable of storing electronic information. ‘Memory’ may refer to various types of processor-readable media, such as random access memory (RAM), read-only memory (ROM), non-volatile random access memory (NVRAM), programmable read-only memory (PROM), erasable programmable read-only memory (EPROM), electrically erasable PROM (EEPROM), flash memory, magnetic or optical data storage devices, registers, and the like. A memory is said to be in electronic communication with a processor if the processor can read information from and/or write information to the memory. Memory integrated into a processor is in electronic communication with the processor.

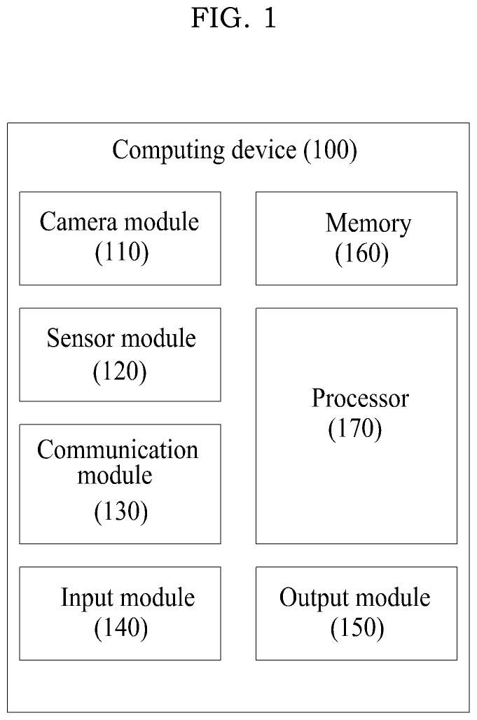

Hereinafter, the present invention includes a computing device 100 (See FIG. 1) for indoor and outdoor wide-area spatial mapping and a method of operation thereof. The computing device 100 may acquire a plurality of datasets for a wide-area space and register the datasets. In some embodiments, the computing device 100 may be implemented in a device such as an apparatus that is carried or worn by a user and is movable by the user, or an autonomously driving robot. In this case, the computing device 100 may directly collect a plurality of datasets while moving inside the wide-area space. In other embodiments, the computing device 100 may be implemented in a server communicating with the device. In this case, the device may collect a plurality of datasets while moving inside the wide-area space, and the computing device 100 may receive the plurality of datasets from the device. Each of the datasets may be for at least a partial area of the wide-area space. One dataset may be divided into at least two different sub-datasets. Here, for at least some of the datasets, corresponding areas may partially overlap. For example, a point where collection for a first dataset ends and a point where collection for a second dataset begins may be identical. Similarly, for at least some of the sub-datasets, corresponding areas may partially overlap. As used herein, the term “wide-area space” refers to a space for which spatial information is generated based on registration of a plurality of datasets collected from different portions of the space.

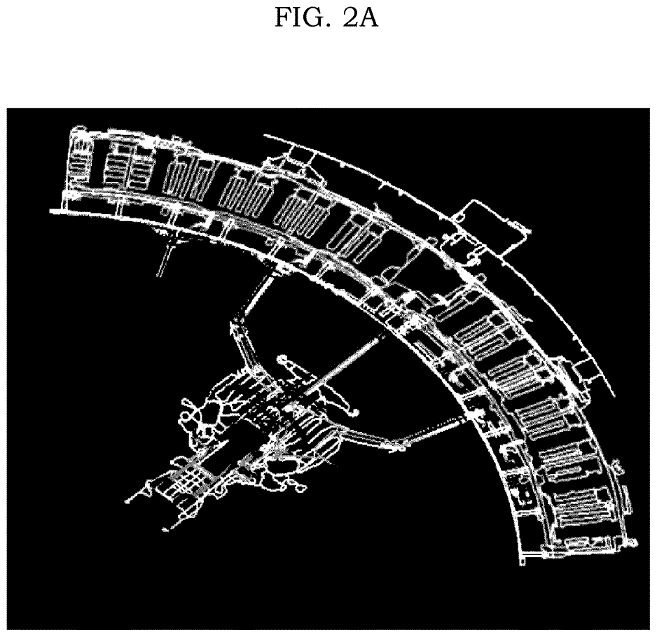

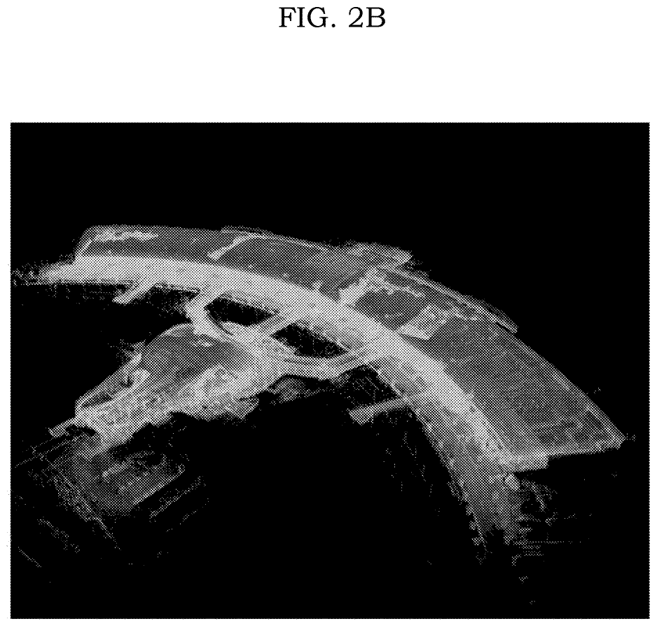

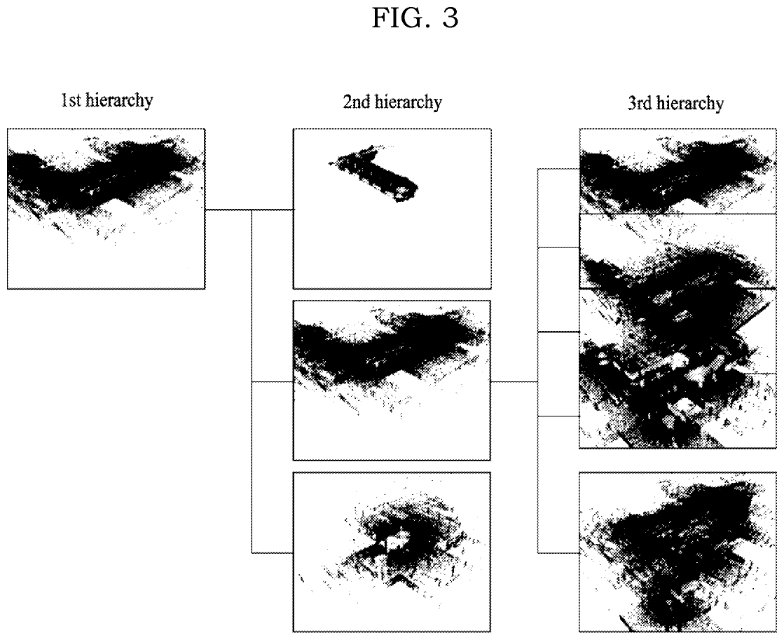

FIG. 1 is a block diagram illustrating the computing device 100 for indoor and outdoor wide-area spatial mapping according to one embodiment. FIG. 2A is an exemplary diagram for explaining collection paths for each of the datasets acquired in the computing device 100 of FIG. 1, and FIG. 2B is an exemplary diagram for explaining registration of the datasets by the computing device 100 of FIG. 1. FIG. 3 is an exemplary diagram for explaining collection of the datasets acquired in the computing device 100 of FIG. 1.

Referring to FIG. 1, the computing device 100 may include a camera module 110, a sensor module 120, a communication module 130, an input module 140, an output module 150, a memory 160, and a processor 170. In some embodiments, at least any one of the components of the computing device 100 may be omitted. In some embodiments, at least one other component may be added to the computing device 100. In some embodiments, at least any two of the components of the computing device 100 may be implemented as a single integrated circuit.

The camera module 110 may photograph a surrounding environment of the computing device 100 to acquire an image thereof. For example, the image may include a moving image or a still image. According to an embodiment, the camera module 110 may include at least one lens, at least one image sensor, an image signal processor, or a flash.

The sensor module 120 may detect the state of the surrounding environment of the computing device 100 to generate an electrical signal or a data value corresponding thereto. The sensor module 120 may include, for example, at least one of a LiDAR sensor, a radar sensor, an infrared (IR) sensor, or a distance sensor. Additionally, the sensor module 120 may detect the operating state of the computing device 100 to generate an electrical signal or a data value corresponding thereto. In this case, the sensor module 120 may further include at least one of a gesture sensor, a gyro sensor, a barometric pressure sensor, a magnetic sensor, an acceleration sensor, a grip sensor, a proximity sensor, a color sensor, an infrared sensor, a biometric sensor, a temperature sensor, a humidity sensor, or an illuminance sensor.

The communication module 130 may perform communication with external devices outside the computing device 100. For example, an external device may include a base station, a server, or a satellite. The communication module 130 may include at least one of a wired communication module or a wireless communication module. The wired communication module may be connected to the external device by wire through a connection terminal (not shown) to communicate with the external device by wire. The wireless communication module may include at least any one of a short-range communication module or a long-range communication module. The short-range communication module may communicate with the external device in a short-range communication manner. For example, the short-range communication manner may include at least any one of Bluetooth, Wi-Fi Direct, or infrared communication. The long-range communication module may communicate with the external device in a long-range communication manner. Here, the long-range communication module may communicate with the external device through a network. For example, the network may include at least any one of a cellular network, the Internet, or a computer network such as a LAN or a WAN. In some embodiments, the communication module 130 may receive GNSS (global navigation satellite system) information. As an example, the GNSS information may include GPS (global positioning system) information.

The input module 140 may input a signal to be used for at least one component of the computing device 100. In some embodiments, the input module 140 may include at least any one of a microphone, a mouse, or a keyboard. In other embodiments, the input module 140 may include at least any one of a touch circuitry configured to detect a touch, or a sensor circuitry configured to measure an intensity of a force generated by the touch.

The output module 150 may output information from the computing device 100. The output module 150 may include at least one of a display module for visually displaying information, or an audio module for audibly reproducing information. For example, the display module may include at least any one of a display, a hologram device, or a projector. As an example, the display module may be assembled with at least any one of the touch circuitry or the sensor circuitry of the input module 140 to be implemented as a touch screen. For example, the audio module may include at least any one of a speaker, a receiver, an earphone, or a headphone.

The memory 160 may store various data used by at least one component of the computing device 100. For example, the memory 160 may include at least any one of a volatile memory or a non-volatile memory. The data may include at least one program and input data or output data related thereto. The program may be stored in the memory 160 as software including at least one instruction.

The processor 170 may execute the program of the memory 160 to control at least one component of the computing device 100. In this manner, the processor 170 may perform data processing or calculation. Here, the processor 170 may execute an instruction stored in the memory 160.

In various embodiments, the processor 170 may acquire a plurality of datasets for a wide-area space. Each of the datasets may be for at least a partial area of the wide-area space. In some embodiments, while the computing device 100 moves inside the wide-area space, the processor 170 may directly collect the datasets. In this case, the processor 170 may collect the datasets through at least one of the camera module 110, the sensor module 120, or the communication module 130. In other embodiments, a separate device may collect the datasets while moving inside the wide-area space. In this case, the processor 170 may receive the datasets from the separate device through the communication module 130. For example, the computing device 100 or the separate device collects the datasets while moving along collection paths distinguished by different colors within the wide-area space as shown in FIG. 2A, and thereby, the processor 170 may acquire the datasets respectively corresponding to the collection paths.

In various embodiments, the processor 170 may update the datasets to each have information on at least one connection point (which may also be referred to as connection point information). The connection point information may include location information of the connection point within the wide-area space and time information upon visiting the connection point. To this end, the processor 170 may designate a connection point between datasets or within a dataset for each of the datasets, and generate connection point information for the corresponding connection point. Here, the connection point may be designated by a user selection or designated based on a preset condition. As used herein, the term “connection point” refers to a point associated with a location within a wide-area space and used for registration between a plurality of datasets or between a plurality of sub-datasets.

In some embodiments, the processor 170 may update the dataset by directly designating a connection point for each dataset. For example, for a dataset acquired for at least a partial area of the wide-area space, the processor 170 may display a pre-stored spatial shape for the corresponding area through the display module. Here, the spatial shape may be a drawing or a rough map briefly representing at least a partial area of the wide-area space. Then, the processor 170 may select at least one connection point within the spatial shape by a user input through the input module 140, and generate connection point information for the selected connection point. Thereby, the processor 170 may update the corresponding dataset to include the generated connection point information.

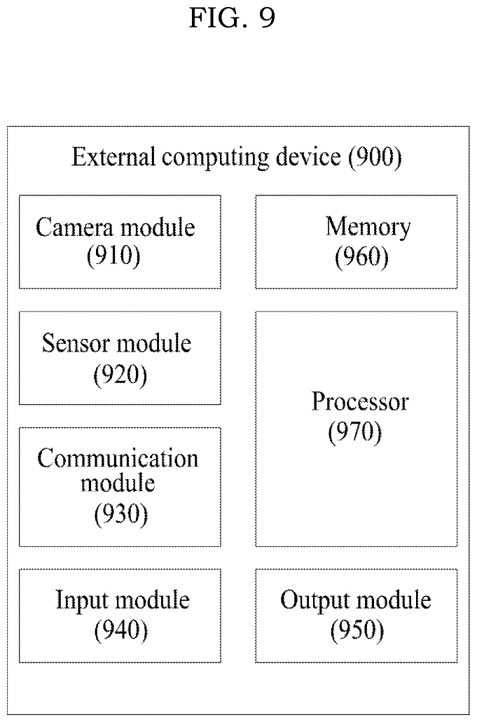

In other embodiments, the processor 170 may update the dataset by designating a connection point for each dataset through an external device (the external computing device 900 of FIG. 9). For example, for a dataset acquired for at least a partial area of the wide-area space, the external computing device 900 may display a pre-stored spatial shape for the corresponding area. Here, the spatial shape may be a drawing or a rough map briefly representing at least a partial area of the wide-area space. Then, the external computing device 900 may select at least one connection point within the spatial shape by a user input, generate location information of the selected connection point, and transmit the location information of the selected connection point to the computing device 100. Accordingly, the processor 170 may receive the location information of the selected connection point through the communication module 130, and generate connection point information of the selected connection point using the received connection point information. Thereby, the processor 170 may update the corresponding dataset to include the generated connection point information. Here, the external computing device 900 may include, for example, at least any one of a smart phone, a mobile phone, a navigation device, a computer, a laptop, a digital broadcasting terminal, a PDA (personal digital assistants), a PMP (portable multimedia player), a tablet PC, a game console, a wearable device, an IoT (internet of things) device, a VR (virtual reality) device, an AR (augmented reality) device, or a robot.

In various embodiments, the processor 170 may register the datasets. At this time, the processor 170 may register the datasets by mapping the connection points of the datasets. As used herein, the term “registration” refers to establishing correspondence between two or more datasets and aligning the datasets based on the established correspondence. In some embodiments, the processor 170 may detect connection points of identical location information (being within a preset distance), detect datasets each having time information of the corresponding connection points, and register these datasets. In other embodiments, the processor 170 may detect connection points of identical location information (being within a preset distance), detect at least two different sub-datasets within one dataset each having time information of the corresponding connection points, and register these sub-datasets. At this time, a plurality of partial spaces within the wide-area space, for example, a first basement floor and a first ground floor, may be clearly distinguished within the registered datasets. Thereby, the processor 170 may obtain a single point cloud for the wide-area space. For example, the processor 170 may register the datasets to obtain a point cloud as shown in FIG. 2B. Therefore, the processor 170 may provide a service for the wide-area space based on the registered datasets, that is, the point cloud. For example, the service may include at least one of map production or a visual localization service. Here, as the plurality of partial spaces within the wide-area space are clearly distinguished, when providing the visual localization service, meta information indicating the partial space to which the current location belongs as well as location information on the current location may be obtained.

In some embodiments, data of the datasets may be divided into service data and remaining data upon collection. The service data may be for at least one inner space to be produced as a map within the wide-area space, and the remaining data may be for a connection space between different inner spaces within the wide-area space. Here, the connection space may include, for example, an elevator, an escalator, stairs, and the like. Therefore, the processor 170 may acquire and register such datasets, and provide a service for the wide-area space based on the registered datasets. Here, since the service data is already divided upon collection, it does not need to be separately selected to provide the service. In other words, a step of separately selecting the service data to provide the service may be omitted.

In other embodiments, data of the datasets may be hierarchically divided into an outdoor space and an indoor space, or each floor of the indoor space for the wide-area space upon collection. Therefore, the processor 170 may acquire such datasets and register the datasets hierarchically, that is, from a lowest hierarchy to a highest hierarchy, which may make a calculation speed of a process of registering the datasets faster. For example, as shown in FIG. 3, point clouds of a lowest third hierarchy (1st floor, 2nd floor, 5th floor, and a connection space between the 1st floor, 2nd floor, and 5th floor) may be generated, point clouds of a first hierarchy may be combined to generate point clouds of an intermediate second hierarchy (outdoor space, indoor space (1st floor, 2nd floor, 5th floor, and a connection space between the 1st floor, 2nd floor, and 5th floor)), and point clouds of the second hierarchy may be combined to generate a point cloud of a highest first hierarchy (wide-area space). As a result, the processor 170 may provide a service for the wide-area space based on the registered datasets.

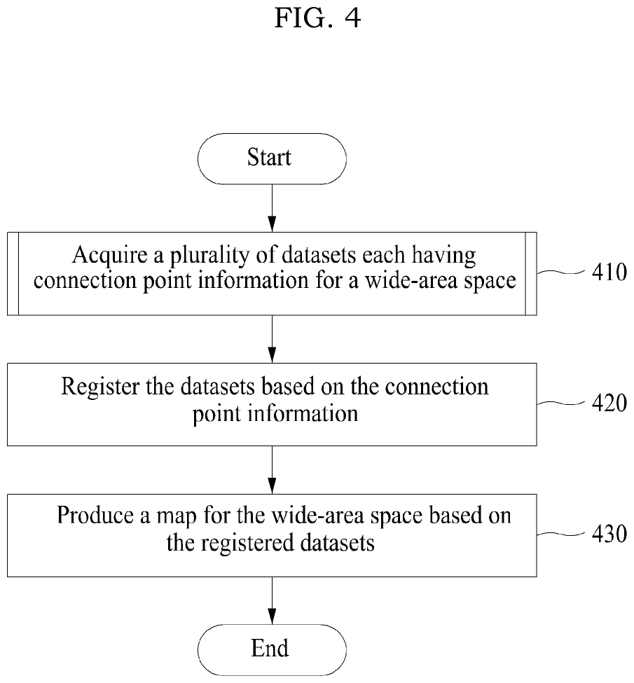

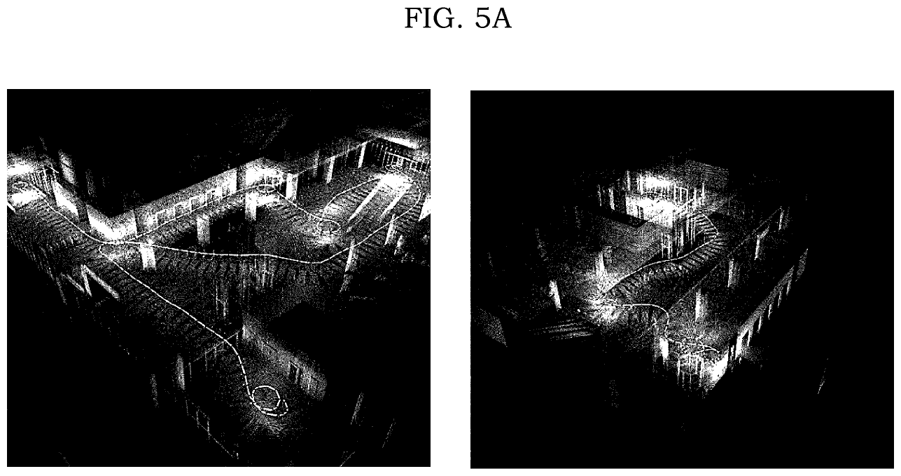

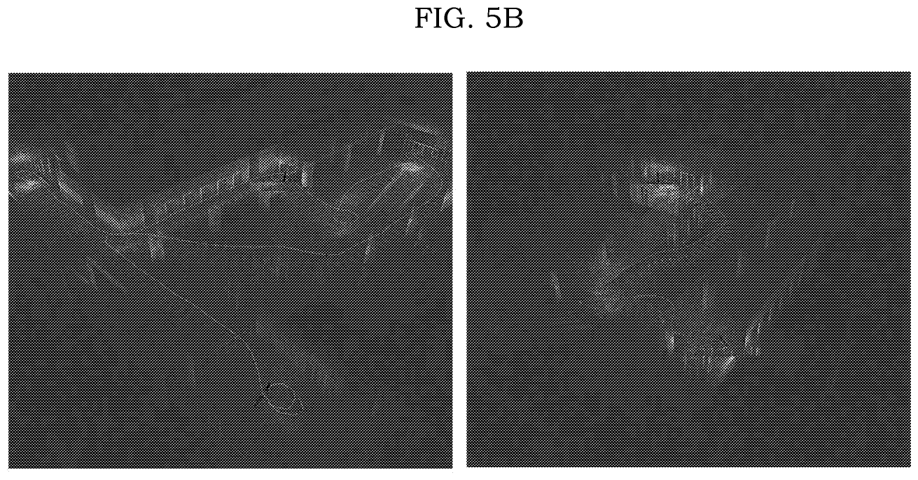

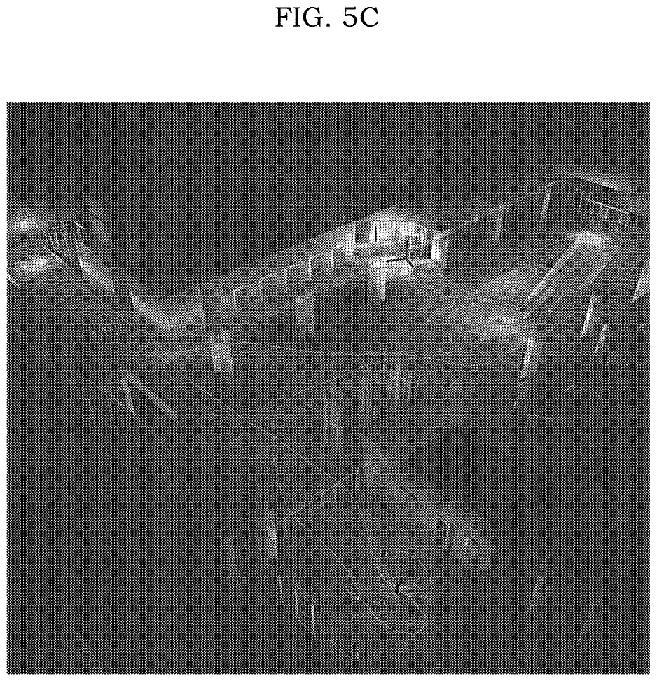

FIG. 4 is a flowchart illustrating a method of operation of the computing device 100 for indoor and outdoor wide-area spatial mapping according to one embodiment. FIG. 5A is an exemplary diagram showing datasets acquired in the computing device 100 of FIG. 1, FIG. 5B is an exemplary diagram showing datasets updated with connection point information from the datasets of FIG. 5A, and FIG. 5C is an exemplary diagram showing registration of the datasets of FIG. 5B.

Referring to FIG. 4, the computing device 100 may acquire a plurality of datasets each having connection point information for the wide-area space in step 410. Specifically, the processor 170 may acquire a plurality of datasets for the wide-area space. Each of the datasets may be for at least a partial area of the wide-area space. At this time, the processor 170 may update the datasets to each have connection point information for at least one connection point. The connection point information may include location information of the connection point within the wide-area space and time information upon visiting the connection point. To this end, the processor 170 may designate a connection point between datasets or within a dataset for each of the datasets, and generate connection point information for the corresponding connection point. For example, the processor 170 may acquire datasets as shown in FIG. 5A, and then update the datasets to each have connection point information for at least one connection point as shown in FIG. 5B. Here, the connection point may be designated by a user selection or designated based on a preset condition. The connection point may be directly designated in the computing device 100 or designated through the external computing device 900, which will be described in more detail below.

Continuing, the computing device 100 may register the datasets based on the connection point information in step 420. Specifically, the processor 170 may register the datasets by mapping the connection points of the datasets. In some embodiments, the processor 170 may detect connection points of identical location information (being within a preset distance), detect datasets each having time information of the corresponding connection points, and register these datasets. In other embodiments, the processor 170 may detect connection points of identical location information (being within a preset distance), detect at least two different sub-datasets within one dataset each having time information of the corresponding connection points, and register these sub-datasets. Thereby, the processor 170 may obtain a single point cloud for the wide-area space. For example, the processor 170 may register the datasets by mapping the connection points of the datasets as shown in FIG. 5C. At this time, a plurality of partial spaces within the wide-area space, for example, a first basement floor and a first ground floor, may be clearly distinguished within the registered datasets.

In some embodiments, data of the datasets may be divided into service data and remaining data upon collection. The service data may be for at least one inner space to be produced as a map within the wide-area space, and the remaining data may be for a connection space between different inner spaces within the wide-area space. Here, the connection space may include, for example, an elevator, an escalator, stairs, and the like. Therefore, the processor 170 may acquire and register such datasets. In other embodiments, data of the datasets may be hierarchically divided into an outdoor space and an indoor space, or each floor of the indoor space for the wide-area space upon collection. Therefore, the processor 170 may acquire such datasets and register the datasets hierarchically, that is, from a lowest hierarchy to a highest hierarchy.

Finally, the computing device 100 may provide a service for the wide-area space based on the registered datasets in step 430. Specifically, the processor 170 may provide a service based on the point cloud for the wide-area space. For example, the service may include at least one of map production or a visual localization service. Here, as the plurality of partial spaces within the wide-area space are clearly distinguished, when providing the visual localization service, meta information indicating the partial space to which the current location belongs as well as location information on the current location may be obtained.

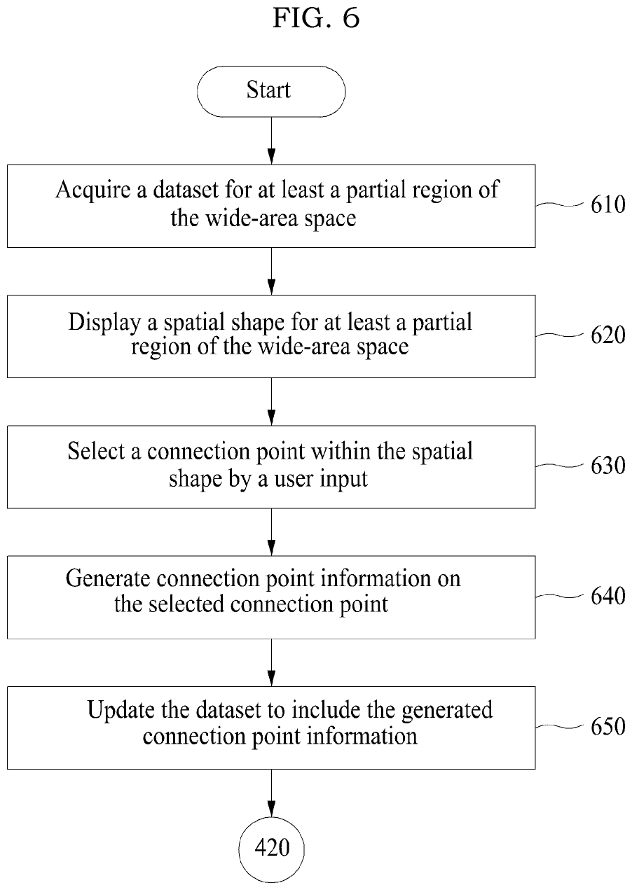

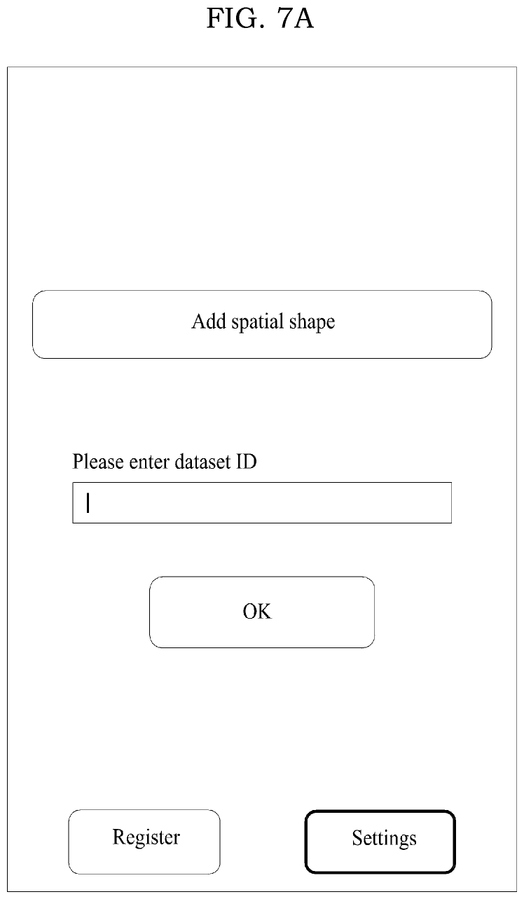

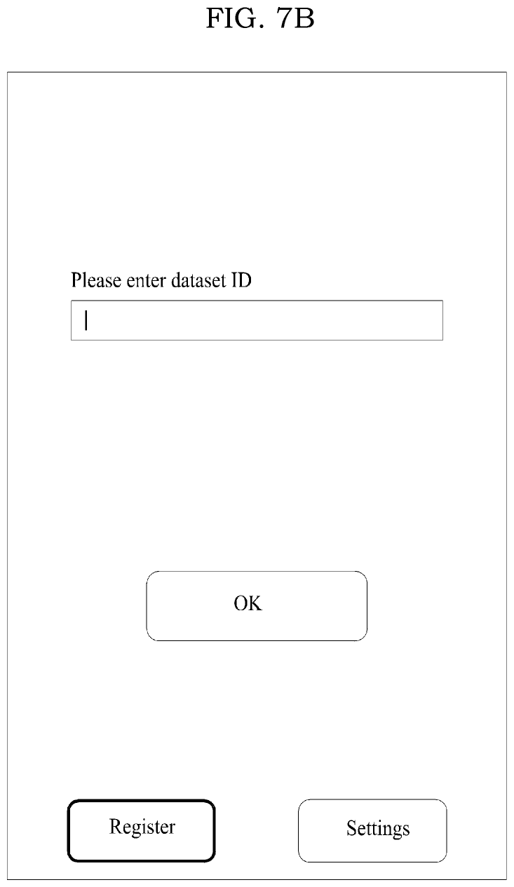

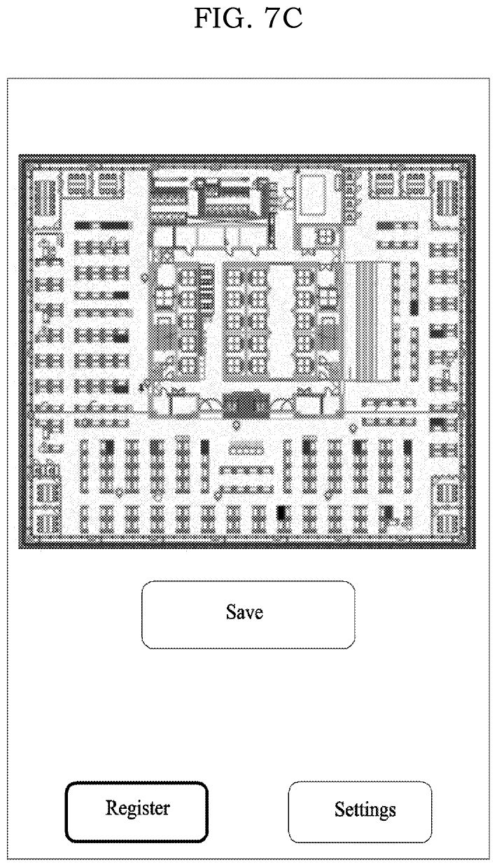

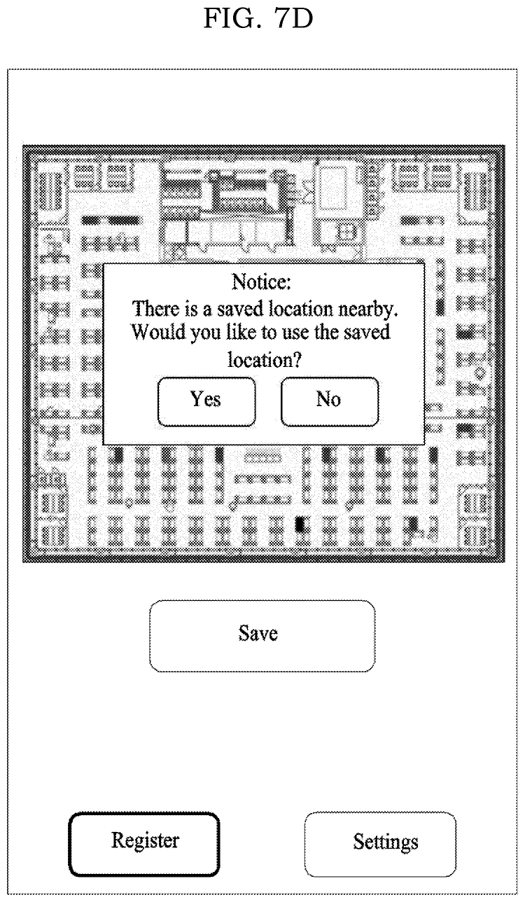

FIG. 6 is a flowchart illustrating the steps of acquiring a plurality of datasets each having connection point information for the wide-area space in step 410 of FIG. 4 according to one embodiment. FIGS. 7A to 7D are exemplary diagrams for explaining a user interface related to FIG. 6. In these embodiments, the connection point may be directly generated in the computing device 100.

Referring to FIG. 6, the computing device 100 may acquire a dataset for at least a partial area of the wide-area space in step 610. In some embodiments, while the computing device 100 moves inside the corresponding area, the processor 170 may directly collect the dataset. In this case, the processor 170 may collect the dataset through at least one of the camera module 110, the sensor module 120, or the communication module 130. In other embodiments, a separate device may collect the dataset while moving inside the wide-area space. In this case, the processor 170 may receive the dataset from the separate device through the communication module 130.

Next, the computing device 100 may display a spatial shape for the corresponding area in step 620. Specifically, the processor 170 may display the corresponding spatial shape through the display module of the output module 150. In an embodiment, the processor 170 may display the corresponding spatial shape in response to a user's request while acquiring the dataset. In another embodiment, the processor 170 may display the corresponding spatial shape in response to a user's request after acquiring all datasets. To this end, a spatial shape for at least a partial area of the wide-area space may be stored in the memory 160. Here, the spatial shape may be a drawing or a rough map briefly representing at least a partial area of the wide-area space. For example, the spatial shape may be downloaded from a design company of the wide-area space or the Internet through the communication module 130, or input through the input module 140. For example, the processor 170 may display a screen on the display module of the output module 150 as shown in FIG. 7A, and based on this, pre-store an identifier (e.g., ID) of the corresponding dataset and the corresponding spatial shape by a user input. Thereafter, the processor 170 may display a screen as shown in FIG. 7B, detect the identifier of the corresponding dataset input by the user based on this, and then display the corresponding spatial shape with a screen as shown in FIG. 7C in response thereto.

Subsequently, the computing device 100 may select at least one connection point within the corresponding spatial shape by a user input in step 630. Specifically, while displaying the corresponding spatial shape, the processor 170 may select a connection point within the spatial shape by a user input through the input module 140. For example, while the corresponding spatial shape is displayed as shown in FIG. 7C, the processor 170 may select a connection point within the corresponding spatial shape by a user's input, and thereby, display an indicator corresponding to the selected connection point within the corresponding spatial shape as shown in FIG. 7C.

Additionally, the processor 170 may determine whether there is an already selected connection point adjacent to the selected connection point. At this time, if there is no already selected connection point, the processor 170 may display an indicator corresponding to the selected connection point within the corresponding spatial shape. If there is an already selected connection point, the processor 170 may display a notification message as shown in FIG. 7D to determine whether to maintain the selected connection point. Here, when maintaining the selected connection point, the processor 170 may add an indicator corresponding to the selected connection point within the corresponding spatial shape. Otherwise, the processor 170 may not add an indicator corresponding to the selected connection point within the corresponding spatial shape.

Continuing, the computing device 100 may generate connection point information for the selected connection point in step 640. The connection point information may include location information of the connection point within the wide-area space and time information upon visiting the connection point. Here, the location information may include identification information for the spatial shape and location coordinates of the connection point within the spatial shape. The time information may be in units of less than a second, for example, in units of microseconds. Specifically, the processor 170 may identify the location information of the connection point for the corresponding spatial shape, and identify a time point when the computing device 100 or the device visited the corresponding connection point upon collecting the corresponding dataset as the time information.

Finally, the computing device 100 may update the corresponding dataset to include the generated connection point information in step 650. Specifically, the processor 170 may update the corresponding dataset by adding the connection point information to the corresponding dataset. Thereby, the dataset may include not only data collected by the computing device 100 or the device but also the connection point information. Thereafter, the computing device 100 may proceed to step 420 of FIG. 4.

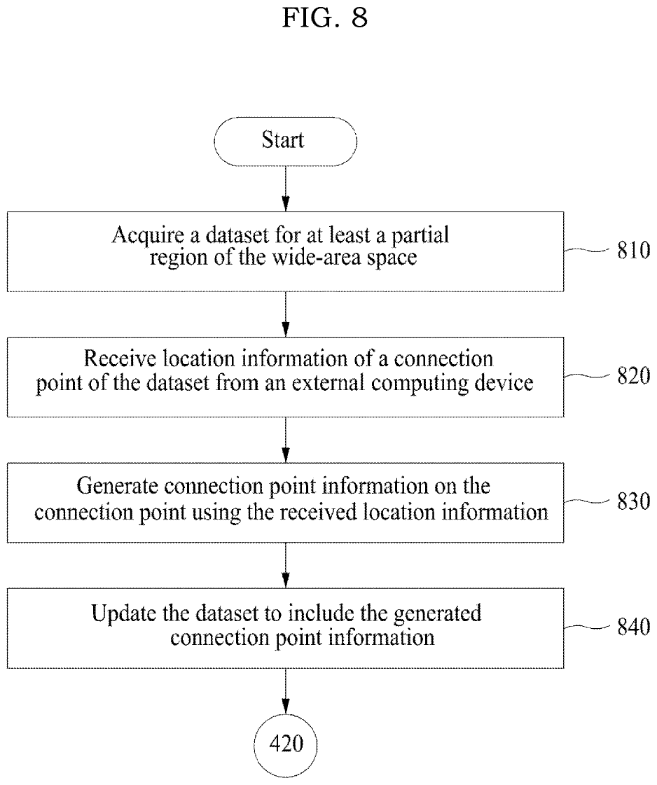

FIG. 8 is a flowchart illustrating the steps of acquiring a plurality of datasets each having connection point information for the wide-area space in step 410 of FIG. 4 according to another embodiment. In these embodiments, the connection point may be designated through the external computing device 900.

Referring to FIG. 8, the computing device 100 may acquire a dataset for at least a partial area of the wide-area space in step 810. In some embodiments, while the computing device 100 moves inside the corresponding area, the processor 170 may directly collect the dataset. In this case, the processor 170 may collect the dataset through at least one of the camera module 110, the sensor module 120, or the communication module 130. In other embodiments, a separate device may collect the dataset while moving inside the wide-area space. In this case, the processor 170 may receive the dataset from the separate device through the communication module 130.

Subsequently, the computing device 100 may receive location information of at least one connection point of the corresponding dataset from the external computing device 900 in step 820. The location information may indicate the location of the connection point within the wide-area space. Here, the location information may include identification information for a spatial shape for at least a partial area of the wide-area space and location coordinates of the connection point within the spatial shape. Specifically, the processor 170 may receive the location information of the connection point from the external computing device 900 through the communication module 130. In one embodiment, a spatial shape for a partial area of the wide-area space corresponding to the corresponding dataset may be stored in the memory 160. In another embodiment, the processor 170 may further receive a spatial shape for a partial area of the wide-area space corresponding to the corresponding dataset together with the location information from the external computing device 900.

Continuing, the computing device 100 may generate connection point information for the connection point using the received location information in step 830. The connection point information may include location information of the connection point within the wide-area space and time information upon visiting the connection point. Here, the time information may be in units of less than a second, for example, in units of microseconds. Specifically, the processor 170 may use the received location information to identify a time point when the computing device 100 or the device visited the corresponding connection point upon collecting the corresponding dataset as the time information. Thereby, the processor 170 may generate the connection point information with the received location information and the corresponding time information.

Finally, the computing device 100 may update the dataset to include the received connection point information in step 840. Specifically, the processor 170 may update the corresponding dataset by adding the connection point information to the corresponding dataset. Thereby, the dataset may include not only data collected by the computing device 100 or the device but also the connection point information. Thereafter, the computing device 100 may proceed to step 420 of FIG. 4.

FIG. 9 is a block diagram illustrating an external computing device 900 for assisting the computing device 100 of FIG. 1 according to one embodiment.

Referring to FIG. 9, the external computing device 900 may include a camera module 910, a sensor module 920, a communication module 930, an input module 940, an output module 950, a memory 960, and a processor 970. In some embodiments, at least any one of the components of the external computing device 900 may be omitted. In some embodiments, at least one other component may be added to the external computing device 900. In some embodiments, at least any two of the components of the external computing device 900 may be implemented as a single integrated circuit. Here, the external computing device 900 may include, for example, a smart phone, a mobile phone, a navigation device, a computer, a laptop, a digital broadcasting terminal, a PDA, a PMP, a tablet PC, a game console, a wearable device, an IoT device, a VR device, an AR device, or a robot.

The camera module 910 may photograph a surrounding environment of the external computing device 900 to acquire an image thereof. For example, the image may include a moving image or a still image. According to an embodiment, the camera module 910 may include at least one lens, at least one image sensor, an image signal processor, or a flash.

The sensor module 920 may detect the state of the surrounding environment of the external computing device 900 to generate an electrical signal or a data value corresponding thereto. The sensor module 920 may include, for example, at least one of a LiDAR sensor, a radar sensor, an infrared sensor, or a distance sensor. Additionally, the sensor module 920 may detect the operating state of the external computing device 900 to generate an electrical signal or a data value corresponding thereto. In this case, the sensor module 920 may further include at least one of a gesture sensor, a gyro sensor, a barometric pressure sensor, a magnetic sensor, an acceleration sensor, a grip sensor, a proximity sensor, a color sensor, an infrared sensor, a biometric sensor, a temperature sensor, a humidity sensor, or an illuminance sensor.

The communication module 930 may perform communication with external devices outside the external computing device 900. For example, an external device may include the computing device 100, a base station, a server, or a satellite. The communication module 930 may include at least one of a wired communication module or a wireless communication module. The wired communication module may be connected to the external device by wire through a connection terminal (not shown) to communicate with the external device by wire. The wireless communication module may include at least any one of a short-range communication module or a long-range communication module. The short-range communication module may communicate with the external device in a short-range communication manner. For example, the short-range communication manner may include at least any one of Bluetooth, Wi-Fi Direct, or infrared communication. The long-range communication module may communicate with the external device in a long-range communication manner. Here, the long-range communication module may communicate with the external device through a network. For example, the network may include at least any one of a cellular network, the Internet, or a computer network such as a LAN or a WAN. In some embodiments, the communication module 930 may receive GNSS information. As an example, the GNSS information may include GPS information.

The input module 940 may input a signal to be used for at least one component of the external computing device 900. In some embodiments, the input module 940 may include at least any one of a microphone, a mouse, or a keyboard. In other embodiments, the input module 940 may include at least any one of a touch circuitry configured to detect a touch, or a sensor circuitry configured to measure an intensity of a force generated by the touch.

The output module 950 may output information from the external computing device 900. The output module 950 may include at least one of a display module for visually displaying information, or an audio module for audibly reproducing information. For example, the display module may include at least any one of a display, a hologram device, or a projector. As an example, the display module may be assembled with at least any one of the touch circuitry or the sensor circuitry of the input module 940 to be implemented as a touch screen. For example, the audio module may include at least any one of a speaker, a receiver, an earphone, or a headphone.

The memory 960 may store various data used by at least one component of the external computing device 900. For example, the memory 960 may include at least any one of a volatile memory or a non-volatile memory. The data may include at least one program and input data or output data related thereto. The program may be stored in the memory 960 as software including at least one instruction.

The processor 970 may execute the program of the memory 960 to control at least one component of the external computing device 900. In this manner, the processor 970 may perform data processing or calculation. Here, the processor 970 may execute an instruction stored in the memory 960.

In various embodiments, the processor 970 may designate at least one connection point for an arbitrary dataset. Specifically, for a dataset acquired for at least a partial area of a wide-area space, the processor 970 may display a pre-stored spatial shape for the corresponding area through the display module. Here, the spatial shape may be a drawing or a rough map briefly representing at least a partial area of the wide-area space. Then, the processor 970 may select at least one connection point within the spatial shape by a user input through the input module 940, and generate location information for the selected connection point. Thereby, the processor 970 may transmit the location information to the computing device 100 through the communication module 940.

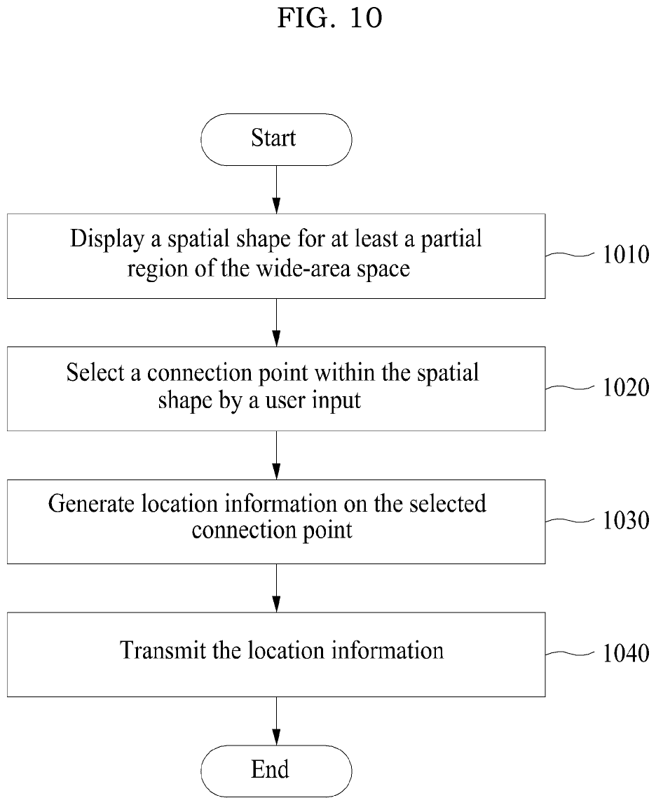

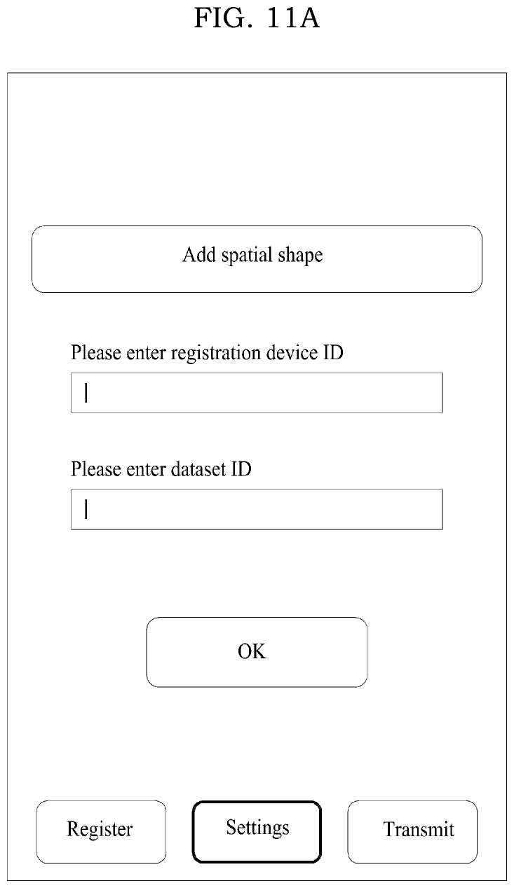

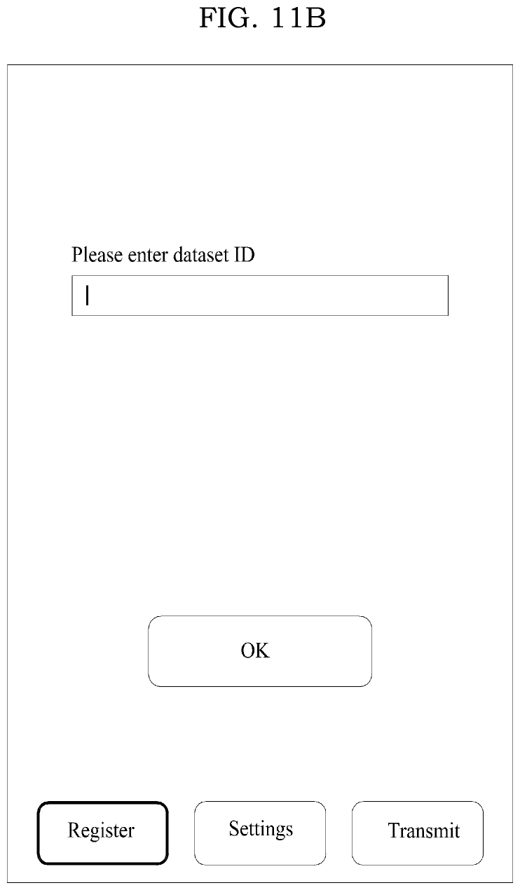

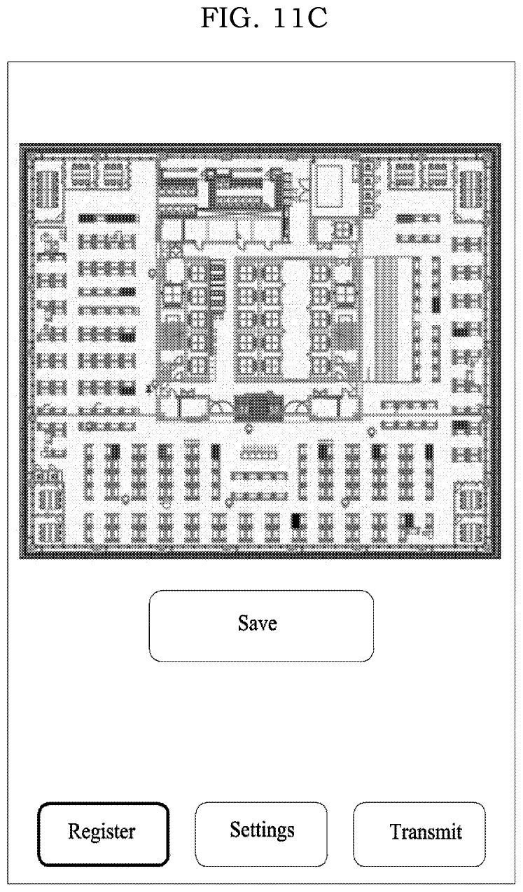

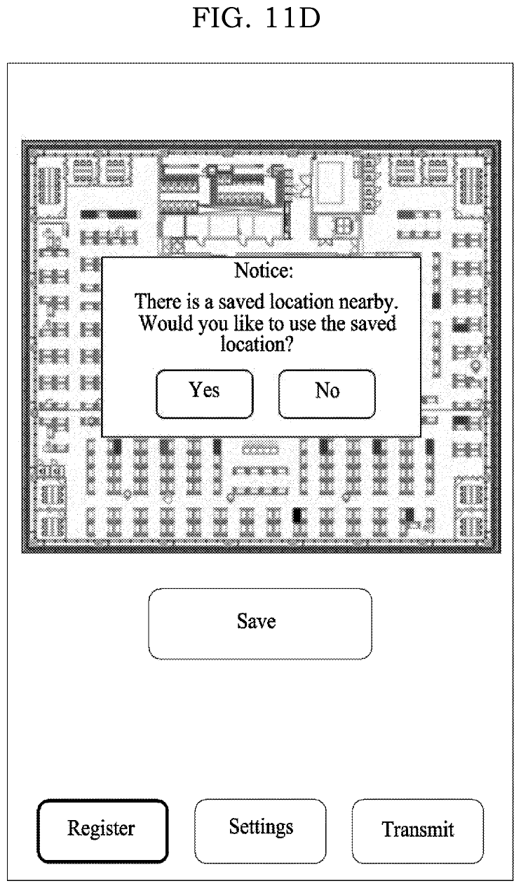

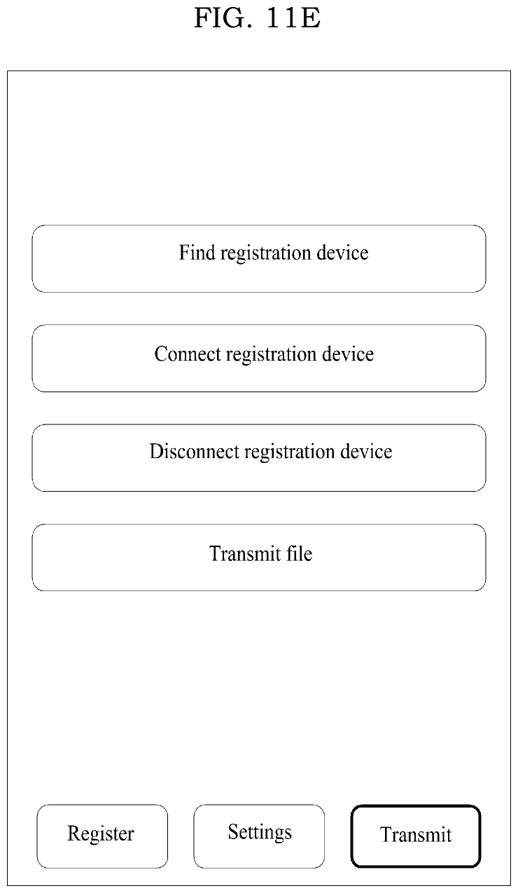

FIG. 10 is a flowchart illustrating a method of operation of the external computing device 900 for assisting the computing device 100 of FIG. 1 according to some embodiments. FIGS. 11A to 11E are exemplary diagrams for explaining a user interface related to FIG. 10.

Referring to FIG. 10, the external computing device 900 may display a spatial shape for at least a partial area of a wide-area space where an arbitrary dataset is acquired in step 1010. Specifically, the processor 970 may display the corresponding spatial shape through the display module. To this end, a spatial shape for at least a partial area of the wide-area space may be stored in the memory 960. Here, the spatial shape may be a drawing or a rough map briefly representing at least a partial area of the wide-area space. For example, the spatial shape may be downloaded from a design company of the wide-area space or the Internet through the communication module 930, or input through the input module 940. For example, the processor 970 may display a screen on the display module of the output module 950, as shown in FIG. 11A, and based on this, pre-store an identifier (e.g., ID) of the corresponding dataset and the corresponding spatial shape by a user input. Along with this, the processor 970 may further store identification information of the computing device 100 from which the corresponding dataset is acquired. Thereafter, the processor 970 may display a screen as shown in FIG. 11B, detect the identifier of the corresponding dataset input by the user based on this, and then display the corresponding spatial shape with a screen as shown in FIG. 11C in response thereto.

Subsequently, the external computing device 900 may select at least one connection point within the corresponding spatial shape by a user input in step 1020. Specifically, while displaying the corresponding spatial shape, the processor 970 may select a connection point within the spatial shape by a user input through the input module 940. For example, while the corresponding spatial shape is displayed as shown in FIG. 11C, the processor 970 may select a connection point within the corresponding spatial shape by a user's input, and thereby, display an indicator corresponding to the selected connection point within the corresponding spatial shape as shown in FIG. 11C.

Additionally, the processor 970 may determine whether there is a connection point already selected adjacent to the selected connection point. At this time, if there is no already-selected connection point, the processor 970 may display an indicator corresponding to the selected connection point within the corresponding spatial shape. If there is a connection point already selected, the processor 170 may display a notification message as shown in FIG. 7D to determine whether to maintain the selected connection point. Here, when maintaining the selected connection point, the processor 170 may add an indicator corresponding to the selected connection point within the corresponding spatial shape. Otherwise, the processor 170 may not add an indicator corresponding to the selected connection point within the corresponding spatial shape.

Continuing, the external computing device 900 may generate location information for the selected connection point in step 1030. The location information may indicate the location of the connection point within the wide-area space. Here, the location information may include identification information for a spatial shape for at least a partial area of the wide-area space and location coordinates of the connection point within the spatial shape. Here, the time information may be in units of less than a second, for example, in units of microseconds. Specifically, the processor 970 may generate location information for the selected connection point based on the corresponding spatial shape.

Finally, the external computing device 900 may transmit the location information to the computing device 100 in step 1040. Specifically, the processor 970 may transmit the location information to the computing device 100 through the communication module 940. The processor 970 may display a screen on the display module of the output module 950, as shown in FIG. 11D, and based on this, transmit the connection point information to the computing device 100. Here, the processor 970 may connect to the computing device 100 through the communication module 940, and then transmit the location information to the computing device 100. In one embodiment, the processor 970 may further transmit the corresponding spatial shape together with the location information.

According to the present disclosure, as each of the datasets includes connection point information, the computing device 100 may more accurately register the datasets using the connection points of the datasets. Specifically, the computing device 100 may register datasets each having connection point information for a connection point of an identical location. Thereby, for example, the computing device 100 may more accurately register datasets respectively collected in different periods, that is, periods separated by an arbitrary time interval. At this time, a plurality of partial spaces within a wide-area space, for example, a first basement floor and a first ground floor, may be clearly distinguished within the registered datasets. Therefore, a possibility of an occurrence of an error in registering the datasets by the computing device 100 may be reduced. In addition, a necessity for the computing device 100 to acquire GPS information together with the datasets may also be eliminated.

In short, the present disclosure describes a computing device 100 for indoor and outdoor wide-area spatial mapping and a method of operation thereof.

The method of operation of the computing device 100 of the present invention may include a step (step 410) of acquiring a plurality of datasets each having connection point information for at least one connection point for a wide-area space, and a step (step 420) of registering the datasets by mapping the connection points of the datasets based

### On the Connection Point Information.

In the present invention, the datasets are collected while moving inside the wide-area space, and the connection point information may include location information of the connection point within the wide-area space and time information upon visiting the connection point.

In the present invention, the step (step 420) of registering the datasets may include a step of registering at least two different datasets by mapping connection points of identical location information.

In the present invention, the step (step 420) of registering the datasets may include a step of registering at least two different sub-datasets within one dataset by mapping connection points of identical location information.

In the present invention, the connection point may be designated by a user selection or designated based on a preset condition.

In the present invention, the step (step 410) of acquiring the datasets may include a step (step 610) of acquiring a dataset for at least a partial area of the wide-area space, a step (step 620) of displaying a pre-stored spatial shape for at least a partial area of the wide-area space, a step (step 630) of selecting at least one connection point within the spatial shape by a user input, a step (step 640) of generating information on the selected connection point, and a step (step 650) of updating the dataset to include the generated information.

In the present invention, the step (step 410) of acquiring the datasets may include a step (step 810) of acquiring a dataset for at least a partial area of the wide-area space, a step (step 820) of receiving location information of a connection point from the external computing device 900, and a step (step 830 and step 840) of updating the dataset to include the received location information.

In the present invention, the external computing device 900 may display a spatial shape (step 1010), select at least one connection point within the spatial shape by a user input (step 1020), generate location information of the selected connection point (step 1030), and transmit the generated location information (step 1040).

In the present invention, the method of operation of the computing device 100 may further include a step (step 430) of providing a service for the wide-area space based on the registered datasets. For example, the service may include at least one of map production or a visual localization service.

In the present invention, data of the datasets may be divided into service data for at least one inner space to be produced as a map within the wide-area space and remaining data for a connection space between different inner spaces within the wide-area space upon collection.

In the present invention, data of the datasets may be hierarchically divided into an outdoor space and an indoor space, or each floor of the indoor space for the wide-area space upon collection.

The computing device 100 of the present invention includes the memory 160, and the processor 170 connected to the memory 160 and configured to execute at least one instruction stored in the memory 160, and the processor 170 may be configured to acquire a plurality of datasets each having information on at least one connection point for a wide-area space, and register the datasets by mapping the connection points of the datasets based on the information.

In the present invention, the datasets are collected while moving inside the wide-area space, and the information may include location information of the connection point within the wide-area space and time information upon visiting the connection point.

In the present invention, the processor 170 may be configured to register at least two different datasets by mapping connection points of identical location information.

In the present invention, the processor 170 may be configured to register at least two different sub-datasets within one dataset by mapping connection points of identical location information.

In the present invention, the computing device 100 further includes a display module in the output module 150 and the input module 140 connected to the processor 170, and the processor 170 may be configured to acquire a dataset for at least a partial area of a wide-area space, display a pre-stored spatial shape for at least a partial area of the wide-area space through the display module, select at least one connection point within the spatial shape by a user input through the input module 140, generate information on the selected connection point, and update the dataset to include the generated information.

In the present invention, the computing device 100 further includes the communication module 130 connected to the processor 170, and the processor 170 is configured to acquire a dataset for at least a partial area of a wide-area space, receive information on a connection point from the external computing device 900 through the communication module, and update the dataset to include the received information, and the external computing device 900 may be configured to display a spatial shape, select at least one connection point within the spatial shape by a user input, generate information on the selected connection point, and transmit the generated information.

In the present disclosure, the processor 170 may be configured to provide a service for a wide-area space based on the registered datasets. For example, the service may include at least one of map production or a visual localization service.

In the present invention, data of the datasets may be divided into service data for at least one inner space to be produced as a map within a wide-area space and remaining data for a connection space between different inner spaces within the wide-area space upon collection.

In the present invention, data of the datasets may be hierarchically divided into an outdoor space and an indoor space, or each floor of the indoor space for a wide-area space upon collection.

The above-described method may be provided as a computer program stored in a computer-readable recording medium for execution in a computer. The medium may continuously store a computer-executable program, or may temporarily store it for execution or download. In addition, the medium may be various recording means or storage means in the form of a single hardware or a combination of several hardware, and is not limited to a medium directly connected to a certain computer system, but may exist distributed on a network. Examples of the medium may include magnetic media such as a hard disk, a floppy disk, and a magnetic tape, optical recording media such as a CD-ROM and a DVD, magneto-optical media such as a floptical disk, and those configured to store program instructions, including a ROM, a RAM, a flash memory, and the like. In addition, as an example of another medium, a recording medium or a storage medium managed by an app store that distributes applications or a site, a server, etc. that supplies or distributes various other software may also be mentioned.

The methods, operations, or techniques of the present disclosure may be implemented by various means. For example, these techniques may be implemented in hardware, firmware, software, or a combination thereof. Those skilled in the art will understand that the various exemplary logical blocks, modules, circuits, and algorithm steps described in connection with the disclosure herein may be implemented as electronic hardware, computer software, or combinations of both. To clearly illustrate this interchangeability of hardware and software, various exemplary components, blocks, modules, circuits, and steps have been described above generally in terms of their functionality. Whether such functionality is implemented as hardware or software depends upon the particular application and design requirements imposed on the overall system. Those skilled in the art may implement the described functionality in varying ways for each particular application, but such implementations should not be interpreted as causing a departure from the scope of the present invention

In a hardware implementation, processing units used to perform the techniques may be implemented within one or more ASICs, DSPs, digital signal processing devices (DSPDs), programmable logic devices (PLDs), field programmable gate arrays (FPGAs), processors, controllers, microcontrollers, microprocessors, electronic devices, other electronic units designed to perform the functions described in the present disclosure, a computer, or a combination thereof.

Accordingly, the various exemplary logical blocks, modules, and circuits described in connection with the present invention may be implemented or performed with a processor, a DSP, an ASIC, an FPGA or other programmable logic device, discrete gate or transistor logic, discrete hardware components, or any combination thereof designed to perform the functions described herein. A processor may be a microprocessor, but in the alternative, the processor may be a controller, a microcontroller, or a state machine. A processor may also be implemented as a combination of computing devices, e.g., a combination of a DSP and a microprocessor, a plurality of microprocessors, one or more microprocessors in conjunction with a DSP core, or any other combination of such configurations.

In a firmware and/or software implementation, the techniques may be implemented as instructions stored on a computer-readable medium such as a random access memory (RAM), a read-only memory (ROM), a non-volatile random access memory (NVRAM), a programmable read-only memory (PROM), an erasable programmable read-only memory (EPROM), an electrically erasable PROM (EEPROM), a flash memory, a compact disc (CD), a magnetic or optical data storage device, and the like. The instructions may be executable by one or more processors, and may cause the processor(s) to perform certain aspects of the functionality described in the present disclosure.

Although the above-described embodiments have been described as utilizing aspects of the presently disclosed subject matter in one or more standalone computer systems, the present disclosure is not limited thereto, and may be implemented in connection with any computing environment such as a network or a distributed computing environment. Furthermore, aspects of the subject matter in the present disclosure may be implemented in a plurality of processing chips or devices, and storage may be similarly affected across a plurality of devices. Such devices may include PCs, network servers, and portable devices.

Although the present invention has been described in connection with some embodiments, various modifications and changes may be made without departing from the scope of the present disclosure that can be understood by a person skilled in the art to which the invention of the present disclosure pertains. In addition, such modifications and changes should be considered to fall within the scope of the claims appended to this specification

What is claimed is:

1. A method of operation of a computing device for wide-area spatial mapping, comprising:
acquiring a plurality of datasets each having connection point information on at least one connection point for a wide-area space; and
registering the datasets by mapping the connection points of the datasets based on the information.

2. The method of operation of a computing device of claim 1, wherein the datasets are collected while moving inside the wide-area space, and
the connection point information includes location information of the connection point within the wide-area space and time information upon visiting the connection point.

3. The method of operation of a computing device of claim 2, wherein the registering of the datasets comprises registering at least two different datasets by mapping the connection points of identical location information.

4. The method of operation of a computing device of claim 2, wherein the registering of the datasets comprises registering at least two different sub-datasets within one dataset by mapping the connection points of identical location information.

5. The method of operation of a computing device of claim 1, wherein the at least one connection point is designated by a user selection or designated based on a preset condition.

6. The method of operation of a computing device of claim 1, wherein the acquiring of the datasets comprises:
acquiring a dataset for at least a partial area of the wide-area space;
displaying a pre-stored spatial shape for the at least a partial area of the wide-area space;
selecting at least one connection point within the spatial shape by a user input;
generating information on the selected connection point; and
updating the dataset to include the generated information.

7. The method of operation of a computing device of claim 1, wherein the step of acquiring the datasets comprises:
acquiring a dataset for at least a partial area of the wide-area space;
receiving information on a connection point from an external device; and
updating the dataset to include the received information, and
wherein the external device displays the spatial shape, selects at least one connection point within the spatial shape by a user input, generates information on the selected connection point, and transmits the generated information.

8. The method of operation of a computing device of claim 1, further comprising providing a service for the wide-area space based on the registered datasets.

9. The method of operation of a computing device of claim 2, wherein data of the datasets are classified, upon collection, into service data for at least one internal space to be produced as a map within the wide-area space and remaining data for a connection space between different internal spaces within the wide-area space.

10. The method of operation of a computing device of claim 2, wherein data of the datasets are hierarchically classified, upon collection, into an outdoor space and an indoor space, or into each floor of an indoor space for the wide-area space.

11. A non-transitory computer-readable recording medium storing a computer program for executing the method of claim 1 on the computing device.

12. A computing device for wide-area spatial mapping, comprising:
a memory; and
a processor connected to the memory and configured to execute at least one instruction stored in the memory,
wherein the processor is configured to execute:
acquiring a plurality of datasets each having connection point information on at least one connection point for a wide-area space, and
registering the datasets by mapping the connection points of the datasets based on the information.

13. The computing device of claim 12, wherein the datasets are collected while moving inside the wide-area space, and
the connection point information includes location information of the connection point within the wide-area space and time information upon visiting the connection point.

14. The computing device of claim 13, wherein the processor is configured to register at least two different datasets by mapping the connection points of identical location information.

15. The computing device of claim 13, wherein the processor is configured to register at least two different sub-datasets within one dataset by mapping the connection points of identical location information.

16. The computing device of claim 12, further comprising a display module and an input module connected to the processor,
wherein the processor is configured to:
acquire a dataset for at least a partial area of the wide-area space,
display a pre-stored spatial shape for the at least a partial area of the wide-area space through the display module,
select at least one connection point within the spatial shape by a user input through the input module,
generate information on the selected connection point, and
update the dataset to include the generated information.

17. The computing device of claim 12, further comprising a communication module connected to the processor,
wherein the processor is configured to:
acquire a dataset for at least a partial area of the wide-area space,
receive information on a connection point from an external device through the communication module, and
update the dataset to include the received information,
and wherein the external device is configured to:
display the spatial shape,
select at least one connection point within the spatial shape by a user input,
generate information on the selected connection point, and
transmit the generated information.

18. The computing device of claim 12, wherein the processor is configured to provide a service for the wide-area space based on the registered datasets.

19. The computing device of claim 13, wherein data of the datasets are classified, upon collection, into service data for at least one internal space to be produced as the map within the wide-area space and remaining data for a connection space between different internal spaces within the wide-area space.

20. The computing device of claim 13, wherein data of the datasets are hierarchically classified, upon collection, into an outdoor space and an indoor space, or into each floor of an indoor space for the wide-area space.
